(19) United States
(12) Patent Application Publication
(10) Pub. No.: US 2011/0287593 A1
(43) Pub. Date: Nov. 24, 2011

(54) METHOD FOR FORMING SEMICONDUCTOR FILM AND METHOD FOR MANUFACTURING SEMICONDUCTOR DEVICE

(75) Inventors: Taichi ENDO, Atsugi (JP); Yutaka YONEMITSU, Atsugi (JP)

(73) Assignee: SEMICONDUCTOR ENERGY LABORATORY CO., LTD., Atsugi (JP)

(21) Appl. No.: 13/107,057

(22) Filed: May 13, 2011

(30) Foreign Application Priority Data
May 20, 2010 (JP) 2010-116128

(51) Int. Cl. H01L 21/336; H01L 21/20

(52) U.S. Cl. 438/197; 438/482; 257/E21.09; 257/E21.411

(57) ABSTRACT

An object is to provide a method for forming an oxide semiconductor film with little variation in electrical characteristics. Another object is to provide a method for manufacturing a semiconductor device including an oxide semiconductor film with little variation in electrical characteristics. To reduce the amount of light scattered by a substrate stage or the amount of the scattered light which travels to enter a light-transmitting oxide semiconductor layer when the light-transmitting oxide semiconductor layer is patterned, a layer having a function of preventing light transmission may be provided in a lower layer than a photoresist layer so that light does not reach the substrate stage. In addition, a semiconductor device may be manufactured using the oxide semiconductor layer formed by the above patterning method.

### BACKGROUND OF THE INVENTION

1. Field of the Invention

The present invention relates to a method for forming an oxide semiconductor film and a method for manufacturing a semiconductor device including an oxide semiconductor film. Note that semiconductor devices herein refer to general elements and devices which function by utilizing semiconductor characteristics.

2. Description of the Related Art

A technique is known in which a semiconductor device is formed using a semiconductor layer formed over a substrate. For example, a technique is known in which a transistor is formed over a glass substrate using a thin film containing a silicon-based semiconductor material and applied to a liquid crystal display device or the like.

As semiconductor materials, amorphous silicon, polycrystalline silicon, and the like are known. Although a transistor formed using amorphous silicon has low field-effect mobility, it has an advantage of being able to be formed over a large glass substrate. Meanwhile, a transistor formed using polycrystalline silicon has high field-effect mobility; however, it needs a crystallization process such as laser annealing and it is not always suitable for a large glass substrate.

As another material, an oxide semiconductor has attracted attention recently. For example, disclosed is a transistor whose active layer includes an amorphous oxide containing indium (In), gallium (Ga), and zinc (Zn) and having an electron carrier concentration of less than 10¹⁸/cm³ (see Patent Document 1).

However, some problems of a transistor including an oxide semiconductor have been pointed out. One of the problems is the stability of the characteristics, and it is pointed out that the electrical characteristics of the transistor are changed by irradiation with visible light and ultraviolet.

### REFERENCE

[Patent Document 1] Japanese Published Patent Application No. 2006-165528

### SUMMARY OF THE INVENTION

In semiconductor devices such as an image display device and an image sensor, electrical characteristics of semiconductor devices such as transistors used therein are particularly important and thus, it is desired that variation in the characteristics be little. For example, in the case of an image display device combining light-emitting elements, variation in on current of a pixel transistor directly influences emission luminance of each pixel.

In view of the above, an object of the present invention is to provide a method for forming an oxide semiconductor film with little variation in electrical characteristics. Further, another object of the present invention is to provide a method for manufacturing a semiconductor device including an oxide semiconductor film with little variation in electrical characteristics.

To achieve the above object, attention is given to an influence of light in a manufacturing process of a semiconductor device, in the present invention.

As light from an exposure apparatus used in a photolithography method, light having a spectrum of a high pressure mercury lamp, such as a g line (with a wavelength of 436 nm), an h line (with a wavelength of 405 nm), or an i line (with a wavelength of 365 nm), or light with a wavelength in the range from an ultraviolet light region to a visible light region, such as KrF laser light (with a wavelength of 248 nm) or ArF laser light (with a wavelength of 193 nm), is used in many cases.

When a semiconductor film is irradiated with light, characteristics thereof are changed in some cases. For example, a thin film transistor including an oxide semiconductor film as a semiconductor layer has a problem that electrical characteristics of the thin film transistor are changed when the oxide semiconductor film is irradiated with light including visible light or ultraviolet in a forming process.

As an example, FIG. 10 shows measurement results of transmittance with respect to wavelengths of light when light having continuous spectrum of wavelengths is delivered to an oxide semiconductor film formed to a thickness of 50 nm by a sputtering method using an In—Ga—Zn—O-based oxide semiconductor as a target. Transmittance tends to lower as the wavelength of irradiation light in the range from an ultraviolet light region to a visible light region is shorter, which shows that the oxide semiconductor film absorbs part of the irradiation light. Therefore, when the oxide semiconductor film is irradiated with light including visible light or ultraviolet used for exposure in a photolithography method described above, such as an i line (with a wavelength of 365 nm) which is light having a spectrum of a high pressure mercury lamp, the oxide semiconductor film absorbs the light, resulting in a change in the electrical characteristics.

Here, it is possible to select a positive photoresist so that light from an exposure apparatus is delivered to only an unnecessary portion, which is to be removed by etching, through a photomask in a step of patterning with a photolithography method. The light from the exposure apparatus might be transmitted through the photoresist to influence a film below the photoresist; however, in the case of using a positive resist, this portion is removed by etching, so that characteristics of a device are not adversely affected.

However, in the case of employing a method for manufacturing a thin film transistor including a semiconductor film which evenly transmits light as a semiconductor layer, over a substrate which transmits light delivered to the substrate from an exposure apparatus, part of light from the exposure apparatus is transmitted through the substrate and the semiconductor layer, scattered by a substrate stage, and then is delivered to the semiconductor layer from the back side of the substrate, in patterning with a photolithography method.

Light is scattered by the substrate stage because of an uneven shape of the substrate stage, which is due to a sucking hole or the like. Thus, scattered light delivered to the back surface of the substrate has intensities and directions different from each other in a substrate surface and the intensities are distributed. As the thickness of the light-transmitting substrate is larger, the distance that the scattered light from the substrate stage travels to enter a portion which is not removed by etching is increased.

Therefore, the scattered light whose intensities are distributed depending on the shape of the substrate stage is delivered to the portion which is not removed by etching of the semiconductor layer, so that influence of light on the semiconductor layer is uneven in the substrate surface.

Thus, scattered light from a substrate stage causes great variation in characteristics particularly in a structure where the scattered light is delivered to an oxide semiconductor layer from the back side, such as a top-gate structure where an oxide semiconductor layer is provided over a light-transmitting substrate or a bottom-gate structure where a light-transmitting material is used for a gate electrode layer.

To solve the above problem, in patterning a light-transmitting oxide semiconductor layer by a photolithography method using a positive photoresist, the amount of light scattered by the substrate stage may be reduced or the amount of the scattered light which travels to enter the light-transmitting oxide semiconductor layer may be reduced. Specifically, it is preferable that light do not reach the substrate stage. That is to say, pattering may be performed while a layer having a function of preventing light transmission is provided in a lower layer than the photoresist layer. In addition, to solve the above problem, a semiconductor device may be manufactured using the oxide semiconductor layer formed by the above patterning method.

One embodiment of the present invention is a method for forming a semiconductor film. The method is as follows. An oxide semiconductor layer is formed over a light-transmitting substrate, an anti-light transmission layer which absorbs or reflects light within a wavelength band absorbed by the oxide semiconductor is formed over the oxide semiconductor layer, and a positive photosensitive photoresist layer is formed over the anti-light transmission layer. Next, the photoresist layer is irradiated with light to which the photoresist layer is sensitive, through a photomask, and a resist mask is formed over the anti-light transmission layer. Further, the anti-light transmission layer is removed except for a portion overlapping with the resist mask and then, the oxide semiconductor layer is removed except for a portion overlapping with the anti-light transmission layer.

When the oxide semiconductor layer is formed by the above forming method, light from an exposure apparatus, which is transmitted through the photomask and the photoresist layer, is mostly absorbed or reflected by the anti-light transmission layer, so that the amount of light which reaches the substrate stage can be reduced effectively. Thus, even when the substrate stage has an uneven shape, the amount of light scattered by the substrate stage, which is delivered to the oxide semiconductor layer from the substrate side, can be reduced. Accordingly, the oxide semiconductor layer can have little variation in electrical characteristics. Further, when such an oxide semiconductor layer is applied to a semiconductor device, the semiconductor device can have little variation in electrical characteristics.

Another embodiment of the present invention is a method for forming a semiconductor film. The method is as follows. An anti-light transmission layer which absorbs or reflects light within a wavelength band absorbed by an oxide semiconductor is formed over a light-transmitting substrate, an oxide semiconductor layer is formed over the anti-light transmission layer, and a positive photosensitive photoresist layer is formed over the oxide semiconductor layer. Next, the photoresist layer is selectively irradiated with light to which the photoresist layer is sensitive, through a photomask, and a resist mask is formed over the oxide semiconductor layer. Further, the oxide semiconductor layer is removed except for a portion overlapping with the resist mask.

When the oxide semiconductor layer is formed by the above forming method, light from an exposure apparatus, which is transmitted through the photomask and the photoresist layer, is mostly absorbed or reflected by the anti-light transmission layer. Further, even when light from the exposure apparatus is not absorbed completely by the anti-light transmission layer and partly reaches the substrate stage, light scattered by the substrate stage is absorbed or reflected by the anti-light transmission layer before reaching the oxide semiconductor layer. Therefore, the amount of light scattered by the substrate stage, which is delivered to the oxide semiconductor layer, can be reduced more effectively. Consequently, the oxide semiconductor layer can have little variation in electrical characteristics. Further, even when the anti-light transmission layer reflects light from the exposure apparatus, a portion of the oxide semiconductor layer, where the light enters, is small because the oxide semiconductor layer is sufficiently thin; thus, electrical characteristics do not vary substantially. Further, when such an oxide semiconductor layer is applied to a semiconductor device, the semiconductor device can have little variation in electrical characteristics.

Another embodiment of the present invention is a method for manufacturing a semiconductor device. The method is as follows. A source electrode layer and a drain electrode layer are formed over a light-transmitting substrate so as to be apart from each other, an oxide semiconductor layer is formed so as to cover end portions of the source electrode layer and the drain electrode layer and a space therebetween, an anti-light transmission layer which absorbs or reflects light within a wavelength band absorbed by the oxide semiconductor is formed over the oxide semiconductor layer, and then a positive photosensitive photoresist layer is formed over the anti-light transmission layer. After that, the photoresist layer is irradiated with light to which the photoresist layer is sensitive, through a photomask, and a resist mask is formed over the anti-light transmission layer so as to overlap with the end portions of the source electrode layer and the drain electrode layer and the space therebetween. Next, the anti-light transmission layer is removed except for a portion overlapping with the resist mask, and the oxide semiconductor layer is removed except for a portion overlapping with the anti-light transmission layer. Further, a gate insulating layer is formed in contact with the oxide semiconductor layer, and a gate electrode layer is formed so as to be in contact with the gate insulating layer and overlap with the space between the source electrode layer and the drain electrode layer.

When the semiconductor device is manufactured by the above manufacturing method, in patterning the oxide semiconductor layer, light from an exposure apparatus, which is transmitted through the photomask and the photoresist layer, is absorbed or reflected by the anti-light transmission layer. Thus, the amount of light scattered by the substrate stage, which travels to enter the oxide semiconductor layer, can be reduced. Accordingly, damage to the oxide semiconductor layer due to light can be suppressed, and thus the semiconductor device can have little variation in electrical characteristics in the substrate surface. By applying such a semiconductor device to an image display device, an image sensor, or the like, the semiconductor device can have little variation in emission luminance or the like.

Another embodiment of the present invention is a method for manufacturing a semiconductor device. The method is as follows. An anti-light transmission layer which absorbs or reflects light within a wavelength band absorbed by an oxide semiconductor is formed over a light-transmitting substrate, an oxide semiconductor layer is formed over the anti-light transmission layer, and a positive photosensitive photoresist layer is formed over the oxide semiconductor layer. After that, the photoresist layer is irradiated with light to which the photoresist layer is sensitive, through a photomask, and a resist mask is formed over the oxide semiconductor layer. Further, the oxide semiconductor layer is removed except for a portion overlapping with the resist mask, a source electrode layer and a drain electrode layer are formed so as to be apart from each other and in contact with the oxide semiconductor layer, and a gate insulating layer is formed in contact with the oxide semiconductor layer and end portions of the source electrode layer and the drain electrode layer. Then, a gate electrode layer is formed so as to be in contact with the gate insulating layer and overlap with the oxide semiconductor layer and a space between the source electrode layer and the drain electrode layer.

When the semiconductor device is manufactured by the above manufacturing method, in patterning the oxide semiconductor layer, light from an exposure apparatus, which is transmitted through the photomask and the photoresist layer, is mostly absorbed or reflected by the anti-light transmission layer. Further, even when light from the exposure apparatus is not absorbed completely by the anti-light transmission layer and partly reaches the substrate stage, light scattered by the substrate stage is absorbed or reflected by the anti-light transmission layer before reaching the oxide semiconductor layer. Therefore, the amount of light scattered by the substrate stage, which is delivered to the oxide semiconductor layer, can be reduced more effectively, resulting in a reduction in the amount of light scattered by the substrate stage, which travels to enter the oxide semiconductor layer. Further, even when the anti-light transmission layer reflects light from the exposure apparatus, a portion of the oxide semiconductor layer, where the light enters, is small because the oxide semiconductor layer is sufficiently thin; thus, electrical characteristics do not vary substantially. Accordingly, damage to the oxide semiconductor layer due to light depending on a pattern of the substrate stage can be suppressed, and thus the semiconductor device can have little variation in electrical characteristics in the substrate surface. By applying such a semiconductor device to an image display device, an image sensor, or the like, the semiconductor device can have little variation in emission luminance or the like.

According to one embodiment of the present invention, a method for forming an oxide semiconductor film with little variation in electrical characteristics can be provided. According to one embodiment of the present invention, a method for manufacturing a semiconductor device including an oxide semiconductor film with little variation in electrical characteristics can be provided.

### BRIEF DESCRIPTION OF THE DRAWINGS

In the accompanying drawings:

FIGS. 1A to 1E illustrate a method for forming an oxide semiconductor film, according to one embodiment of the present invention;

FIGS. 2A and 2B illustrate a thin film transistor manufactured by a manufacturing method according to one embodiment of the present invention;

FIGS. 3A to 3E illustrate a method for manufacturing a thin film transistor, according to one embodiment of the present invention;

FIGS. 4A and 4B illustrate a thin film transistor manufactured by a manufacturing method according to one embodiment of the present invention;

FIGS. 5A and 5B illustrate an effect of an anti-light transmission layer according to one embodiment of the present invention;

FIGS. 6A to 6E illustrate a method for forming an oxide semiconductor film, according to one embodiment of the present invention;

FIGS. 7A and 7B illustrate a thin film transistor manufactured by a manufacturing method according to one embodiment of the present invention;

FIGS. 8A to 8E illustrate a method for manufacturing a thin film transistor, according to one embodiment of the present invention;

FIGS. 9A and 9B each illustrate a thin film transistor manufactured by a manufacturing method according to one embodiment of the present invention; and

FIG. 10 shows measurement results of transmittance of an oxide semiconductor film with respect to wavelengths of light.

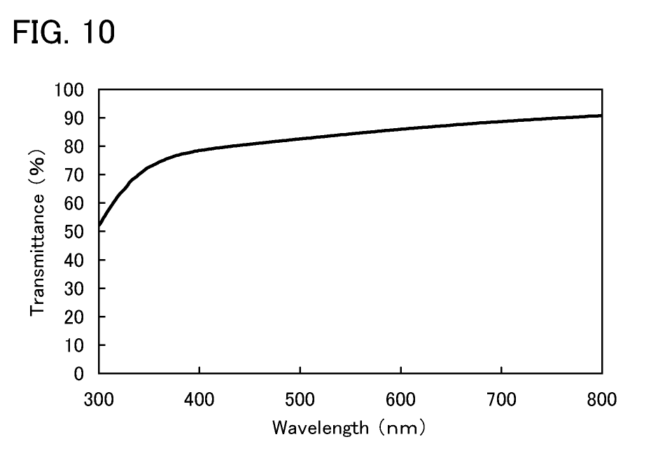

### DETAILED DESCRIPTION OF THE INVENTION

Embodiments will be described with reference to the drawings. Note that the present invention is not limited to the following description, and it will be easily understood by those skilled in the art that various changes and modifications can be made without departing from the spirit and scope of the present invention. Therefore, the present invention should not be construed as being limited to the description in the following embodiments. Note that in the structures of the invention described below, the same portions or portions having similar functions are denoted by the same reference numerals in different drawings, and description of such portions is not repeated.

Note that in each drawing described in this specification, the size, the layer thickness, or the region of each component is exaggerated for clarity in some cases. Therefore, the embodiments of the present invention are not limited to such scales.

### Embodiment 1

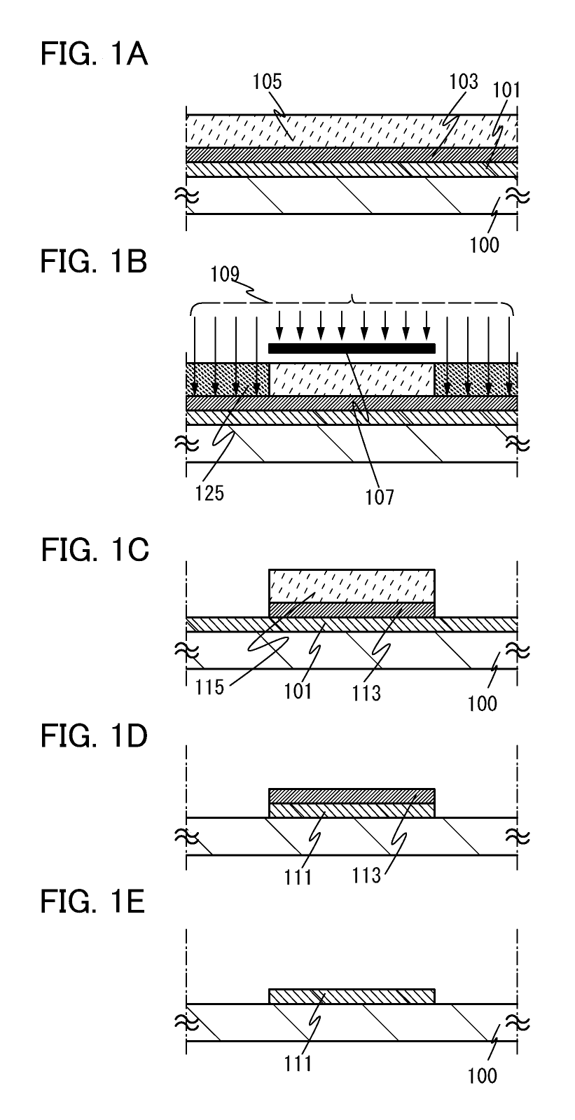

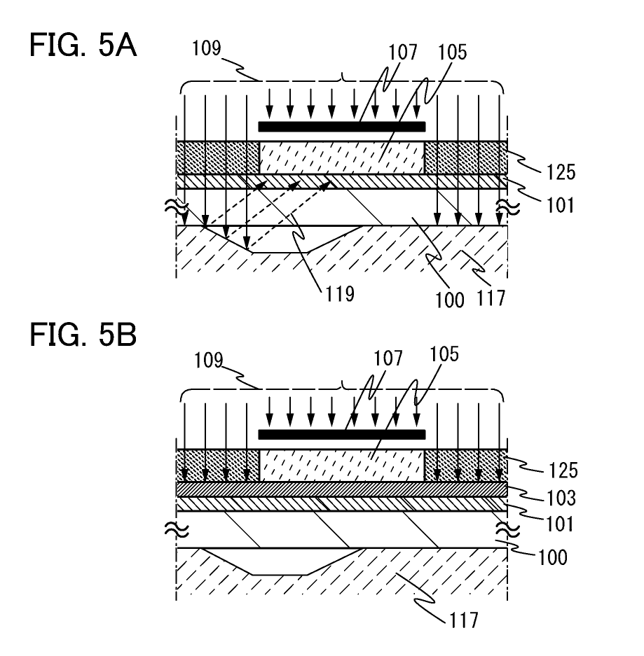

In this embodiment, an example of a method for forming an oxide semiconductor layer, in which patterning is performed by a photolithography method while an adverse effect of light scattered by a substrate stage is suppressed, will be described with reference to FIGS. 1A to 1E and FIGS. 5A and 5B.

Described is a method for forming an island-shaped oxide semiconductor layer 111 exemplified in FIGS. 1D and 1E over a light-transmitting substrate 100.

First, as illustrated in FIG. 1A, an oxide semiconductor layer 101, an anti-light transmission layer 103, and a photoresist 105 are sequentially formed over the light-transmitting substrate 100.

Used as the light-transmitting substrate 100 is a substrate having a higher transmittance of light with a wavelength in the range from an ultraviolet light region to a visible light region than the oxide semiconductor film. Further, there is no particular limitation on a substrate used as the light-transmitting substrate 100 as long as it has an insulating surface; however, in the case where heat treatment is performed in a later step, the substrate needs to have at least heat resistance against the temperature in the heat treatment. For example, a glass substrate made of barium borosilicate glass, aluminoborosilicate glass, or the like can be used.

As an oxide semiconductor used for the oxide semiconductor layer 101 includes at least one element selected from In, Ga, Sn, Zn, Al, Mg, Hf, and lanthanoid. For example, an oxide of four metal elements, such as an In—Sn—Ga—Zn—O-based oxide semiconductor; an oxide of three metal elements, such as an In—Ga—Zn—O-based oxide semiconductor, an In—Sn—Zn—O-based oxide semiconductor, an In—Al—Zn—O-based oxide semiconductor, a Sn—Ga—Zn—O-based oxide semiconductor, an Al—Ga—Zn—O-based oxide semiconductor, a Sn—Al—Zn—O-based oxide semiconductor, an In—Hf—Zn—O-based oxide semiconductor, an In—La—Zn—O-based oxide semiconductor, an In—Ce—Zn—O-based oxide semiconductor, an In—Pr—Zn—O-based oxide semiconductor, an In—Nd—Zn—O-based oxide semiconductor, an In—Pm—Zn—O-based oxide semiconductor, an In—Sm—Zn—O-based oxide semiconductor, an In—Eu—Zn—O-based oxide semiconductor, an In—Gd—Zn—O-based oxide semiconductor, an In—Tb—Zn—O-based oxide semiconductor, an In—Dy—Zn—O-based oxide semiconductor, an In—Ho—Zn—O-based oxide semiconductor, an In—Er—Zn—O-based oxide semiconductor, an In—Tm—Zn—O-based oxide semiconductor, an In—Yb—Zn—O-based oxide semiconductor, or an In—Lu—Zn—O-based oxide semiconductor; or an oxide of two metal elements such as an In—Zn—O-based oxide semiconductor, a Sn—Zn—O-based oxide semiconductor, an Al—Zn—O-based oxide semiconductor, a Zn—Mg—O-based oxide semiconductor, a Sn—Mg—O-based oxide semiconductor, an In—Mg—O-based oxide semiconductor, or an In—Ga—O-based oxide semiconductor; an In—O-based oxide semiconductor; a Sn—O-based oxide semiconductor; a Zn—O-based oxide semiconductor; or the like can be used. Further, SiO₂ may be contained in the above oxide semiconductor. Here, for example, an In—Ga—Zn—O-based oxide semiconductor is an oxide containing at least In, Ga, and Zn, and there is no particular limitation on the composition ratio thereof. Further, the In—Ga—Zn—O-based oxide semiconductor may contain an element other than In, Ga, and Zn.

For the oxide semiconductor layer 101, a thin film expressed by the chemical formula, InMO₃(ZnO)ₘ (m>0), can be used. Here, M represents one or more metal elements selected from Ga, Al, Mn, and Co. For example, M can be Ga, Ga and Al, Ga and Mn, Ga and Co, or the like.

The oxide semiconductor layer 101 can be formed by a sputtering method. Further, the oxide semiconductor layer 101 can be formed in a rare gas (typically, argon) atmosphere, an oxygen atmosphere, or a mixed atmosphere of a rare gas and oxygen. It is preferable that a high-purity gas in which impurities such as hydrogen, water, a hydroxyl group, and hydride are removed be used as the gas for the formation of the oxide semiconductor layer 101.

In this embodiment, the oxide semiconductor layer 101 is formed to a thickness of 100 nm by a sputtering method using an In—Ga—Zn—O-based oxide target.

As a material of the anti-light transmission layer 103, a film which absorbs or reflects light used for exposure in pattering is preferably used; the film needs to absorb or reflect at least light within a wavelength band absorbed by the oxide semiconductor film. For example, in the case where a g line (with a wavelength of 436 nm) which is light having a spectrum of a high pressure mercury lamp is used as light for exposure, it is possible to use a film whose transmittance of light with the wavelength is 20% or lower, further preferably 5% or lower. For example, a semiconductor material such as amorphous silicon or a metal material such as Al can be used.

Here, in patterning the oxide semiconductor layer 101, as a mask used to remove an unnecessary portion of the oxide semiconductor layer 101, a resist mask 115 to be described later may be used, or an anti-light transmission layer 113 may be used as a hard mask. When the anti-light transmission layer 113 is used as a hard mask, a material whose etching selectivity to a material of the oxide semiconductor layer 101 is high is preferably selected as appropriate depending on a selected etching method and used for the anti-light transmission layer 103. For example, in the case where an In—Ga—Zn—O-based material is used for the oxide semiconductor layer 101 and amorphous silicon is used for the anti-light transmission layer 103, only the oxide semiconductor layer 101 can be removed using a mixed acid containing acetic acid, nitric acid, and phosphoric acid, an oxalic acid solution, or the like, and only the anti-light transmission layer 103 can be removed using a tetramethylammonium hydroxide solution or the like.

Being in contact with the oxide semiconductor layer 101, the anti-light transmission layer 103 is preferably formed so as to contain hydrogen as little as possible. For example, the anti-light transmission layer 103 can be formed by a sputtering method in a high-purity gas atmosphere in which impurities such as hydrogen, water, a hydroxyl group, and hydride are removed, similarly to the formation of the oxide semiconductor layer 101.

In this embodiment, the anti-light transmission layer 103 is formed to a thickness of 100 nm by a sputtering method using amorphous silicon.

Used as the photoresist 105 is a so-called positive photoresist which is removed by development treatment when it is irradiated with light. When a positive photoresist is used, only an unnecessary portion of the oxide semiconductor layer is irradiated with light from an exposure apparatus; thus, a necessary pattern can be prevented from being directly irradiated with light.

Next, exposure is performed using a photomask 107 (see FIG. 1B). A portion of the photoresist 105, which is covered with the photomask 107, is shielded from exposure light 109 by the photomask 107 and thus is not exposed to light. On the other hand, a portion of the photoresist 105, which is not covered with the photomask 107, is irradiated with the exposure light 109. The photoresist 105 is exposed to the exposure light 109 to form a modified photoresist 125.

As the exposure light 109, light having a spectrum of a high pressure mercury lamp, such as a g line (with a wavelength of 436 nm), an h line (with a wavelength of 405 nm), or an i line (with a wavelength of 365 nm), or light with a wavelength in the range from an ultraviolet light region to a visible light region, such as KrF laser light (with a wavelength of 248 nm) or ArF laser light (with a wavelength of 193 nm), can be used. In this embodiment, an i line which is light having a spectrum of a high pressure mercury lamp is used as the exposure light 109.

In the case where an i line (with a wavelength of 365 nm) is used as the exposure light 109 here, when the oxide semiconductor layer is irradiated with the i line, it absorbs the i line, so that electrical characteristics thereof are adversely affected.

In the case where amorphous silicon with a thickness of 100 nm is used for the anti-light transmission layer 103, the transmittance of the i line (with a wavelength of 365 nm), which is used as the exposure light 109, of the anti-light transmission layer 103 is lower than 1%; thus, the anti-light transmission layer 103 can absorb most part of the i line.

Here, a difference in influence of scattered light due to the shape of the substrate stage between presence and absence of the anti-light transmission layer will be described with reference to FIGS. 5A and 5B. Note that the shape of the substrate stage illustrated here is only an example and an embodiment of the present invention is not limited thereto.

First, FIG. 5A is a schematic cross-sectional view illustrating the state where exposure is performed on the oxide semiconductor layer 101 in the case where the anti-light transmission layer 103 is not provided. The oxide semiconductor layer 101 and the photoresist 105 are stacked over the substrate 100, and the exposure light 109 is delivered through the photomask 107. The substrate 100 is provided on a substrate stage 117 having an uneven shape.

The uneven shape of the substrate stage 117 is due to, for example, a sucking hole for sucking the substrate, a pin for lifting the substrate, or the like. Further, the uneven shape may be due to a flaw due to contact between the substrate and the substrate stage 117, or the like, surface unevenness of a material itself, or the like.

Part of the exposure light 109 from the exposure apparatus passes through the photoresist 125, is transmitted through the oxide semiconductor layer 101 and the substrate 100, and then reaches the substrate stage 117.

When the substrate stage 117 has such an uneven shape illustrated in the drawing, the exposure light 109 which reaches the substrate stage 117 is scattered by the uneven shape, and scattered light 119 is delivered to a back surface of the substrate 100. The scattered light 119 has a variety of scattering angles depending on the uneven shape of the substrate stage. Therefore, the scattered light 119 delivered to the back surface of the substrate 100 partly travels to enter a portion of the oxide semiconductor layer 101, which is not removed by etching of the oxide semiconductor layer 101.

An increase in thickness of the substrate 100 increases the distance that the scattered light 119 from the substrate stage 117 travels to enter the portion which is not removed by the etching.

Next, the case of providing the anti-light transmission layer 103 will be described with reference to FIG. 5B. The structure in FIG. 5B is the same as that in FIG. 5A, except that the anti-light transmission layer 103 is provided between the oxide semiconductor layer 101 and the photoresist 105.

After passing through the photoresist 125, part of the exposure light 109 reaches the anti-light transmission layer 103 but is mostly absorbed or reflected by the anti-light transmission layer 103. Thus, the exposure light 109 hardly reaches the oxide semiconductor layer 101. Further, the amount of the exposure light 109 which is transmitted through the substrate 100 and reaches the substrate stage 117 is reduced effectively.

Therefore, even when the substrate stage 117 has an uneven shape due to a sucking hole or the like, the amount of the exposure light 109 which reaches the substrate stage 117 and the amount of light scattered by the uneven shape are reduced effectively. Consequently, it is possible to effectively reduce the amount of light scattered by the substrate stage, which travels to enter a portion of the oxide semiconductor layer 101, which is not removed by etching of the oxide semiconductor layer 101. Thus, the oxide semiconductor layer 101 can be prevented from being adversely affected by light.

By thus providing the anti-light transmission layer 103 so that the substrate is closer to the anti-light transmission layer 103 than the photoresist 105, the exposure light 109 is absorbed by the anti-light transmission layer 103 and does not reach the substrate stage 117. Consequently, a necessary portion of the oxide semiconductor layer 101 can be prevented from being adversely affected by light regardless of the uneven shape of the substrate stage 117.

After exposure treatment, development treatment is performed. Through the develop treatment, a portion of the photoresist 125, which is not covered with the photomask 107, is removed. In that manner, the resist mask 115 is formed.

Then, an unnecessary portion of the anti-light transmission layer 103 is etched using the resist mask 115, so that the anti-light transmission layer 113 having an island shape is formed (FIG. 1C). After that, an unnecessary portion of the oxide semiconductor layer 101 is etched using the resist mask 115 and then, the resist mask 115 is removed.

Although the anti-light transmission layer 103 and the oxide semiconductor layer 101 are etched separately in this embodiment, the unnecessary portions of the anti-light transmission layer 103 and the oxide semiconductor layer 101 may be etched using the resist mask 115 at the same time. Either wet etching or dry etching may be employed as an etching method. Dry etching is preferably employed because variation in pattern shape can be reduced as compared to the case of employing wet etching.

In such a manner, a pattern where the anti-light transmission layer 113 is stacked over the oxide semiconductor layer 111 is formed (see FIG. 1D).

In order to form the oxide semiconductor layer 111, it is also possible to remove the resist mask 115 when the anti-light transmission layer 113 is formed, and etch the oxide semiconductor layer using the anti-light transmission layer 113 as a hard mask. In that case, the anti-light transmission layer 113 also functions as a plasma protective film for the oxide semiconductor layer 111; thus, dry etching using plasma can be employed even after the resist mask 115 is removed. Dry etching is preferably employed because variation in pattern shape can be reduced as compared to the case of employing wet etching. Also in the case of employing this method, a shape similar to that in FIG. 1D can be obtained.

After formation of the oxide semiconductor layer 111, the anti-light transmission layer 113 may be removed by etching. The shape obtained in that manner is illustrated in FIG. 1E.

By forming the oxide semiconductor layer 111 as described above, the oxide semiconductor layer 111 can be formed without being adversely affected by light from the exposure apparatus in the patterning. Therefore, when an oxide semiconductor layer formed through such a forming process is applied to a semiconductor device such as a thin film transistor, the semiconductor device can have little variation in electrical characteristics.

This embodiment can be combined as appropriate with any of the other embodiments in this specification.

### Embodiment 2

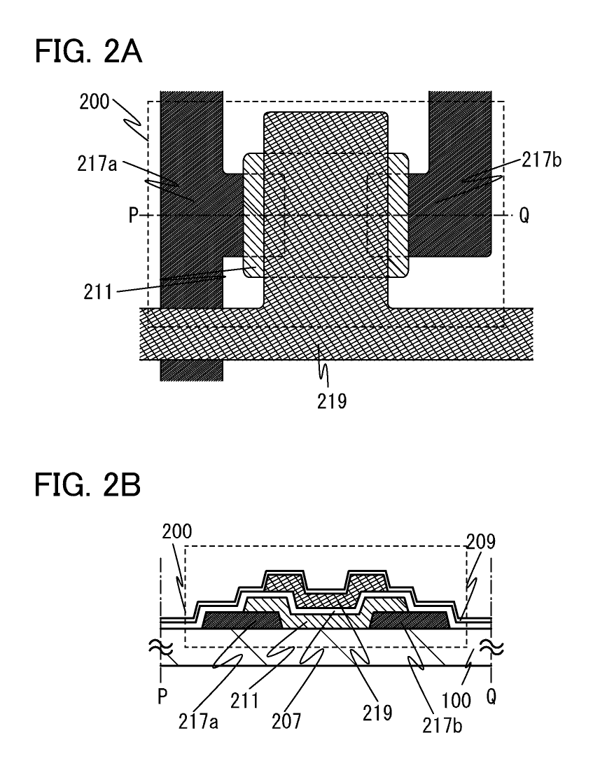

In this embodiment, an example of a method for manufacturing a thin film transistor including the oxide semiconductor layer formed by the forming method in Embodiment 1 will be described with reference to FIGS. 2A and 2B, FIGS. 3A to 3E, and FIGS. 4A and 4B.

FIGS. 2A and 2B illustrate a structure of a staggered thin film transistor 200 (hereinafter referred to as the thin film transistor 200) exemplified in this embodiment. FIGS. 2A and 2B are a schematic top view of the thin film transistor 200 and a schematic cross-sectional view along P-Q in FIG. 2A, respectively.

The thin film transistor 200 includes, over the light-transmitting substrate 100, a source electrode layer 217a and a drain electrode layer 217b, an oxide semiconductor layer 211, a gate insulating layer 207, a gate electrode layer 219, and a protective insulating layer 209. The oxide semiconductor layer 211 is in contact with the source electrode layer 217a and the drain electrode layer 217b and covers a space therebetween. The gate insulating layer 207 covers exposed portions of each of the substrate 100, the source electrode layer 217a and the drain electrode layer 217b, and the oxide semiconductor layer 211. The gate electrode layer 219 is in contact with the gate insulating layer 207 and overlaps with end portions of the source electrode layer 217a and the drain electrode layer 217b and the space therebetween. The protective insulating layer 209 covers the gate insulating layer 207 and the gate electrode layer 219.

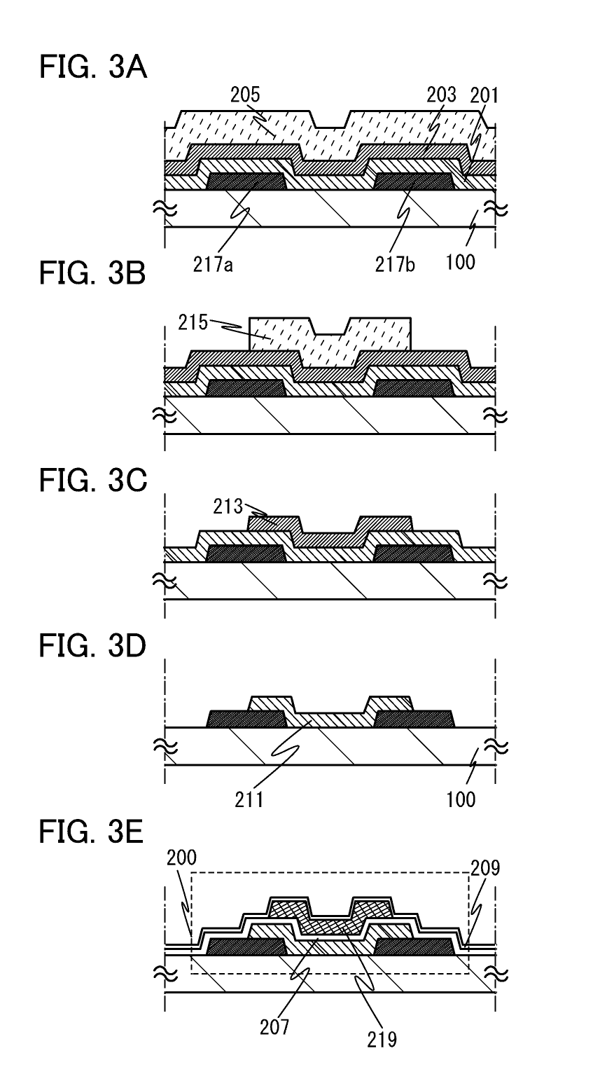

Next, a manufacturing method of the thin film transistor 200 will be described with reference to FIGS. 3A to 3E.

First, the source electrode layer 217a and the drain electrode layer 217b are formed over the substrate 100.

As the substrate 100, a light-transmitting substrate is used as in Embodiment 1. Thus, in the case of such a staggered thin film transistor in this embodiment, when a channel formation region in the oxide semiconductor layer 211 is irradiated with light from the substrate side in a step of patterning the oxide semiconductor layer, the oxide semiconductor layer 211 is adversely affected by light directly.

As a material used for the source electrode layer 217a and the drain electrode layer 217b, an element selected from Al, Cr, Cu, Ta, Ti, Mo, and W, an alloy containing any of these elements, an alloy containing a combination of any of these elements, or the like can be used. Alternatively, a structure may be employed in which a high-melting-point metal film such as a Ti film, a Mo film, or a W film is provided over and/or below a metal film such as an Al film or a Cu film. In addition, heat resistance can be increased by using an Al material to which an element (Si, Nd, Sc, or the like) which prevents generation of a hillock or a whisker in an Al film is added. Alternatively, the source electrode layer 217a and the drain electrode layer 217b may be formed using a conductive metal oxide. As the conductive metal oxide, an indium oxide (In₂O₃), a tin oxide (SnO₂), a zinc oxide (ZnO), an indium oxide-tin oxide alloy (In₂O₃—SnO₂, abbreviated to ITO), an indium oxide-zinc oxide alloy (In₂O₃—ZnO), or any of these metal oxide materials containing a silicon oxide can be used.

Further, an insulating film serving as a base layer may be provided between the substrate 100 and the source and drain electrode layers 217a and 217b. The base layer has a function of preventing diffusion of an impurity element from the substrate 100, and can be formed to have a single-layer structure or a layered structure using any of a silicon nitride film, a silicon oxide film, a silicon nitride oxide film, and a silicon oxynitride film.

Note that the base layer is preferably formed so as to contain impurities such as hydrogen and water as little as possible.

The source electrode layer 217a and the drain electrode layer 217b can be formed in such a manner that a conductive layer is formed over the substrate 100 and is selectively etched through a first photolithography process.

In this embodiment, the source electrode layer 217a and the drain electrode layer 217b are formed in such a manner that a Ti film is formed as a conductive layer to be the source electrode layer 217a and the drain electrode layer 217b to a thickness of 150 nm by a sputtering method, and the first photolithography process is performed.

An oxide semiconductor layer 201, an anti-light transmission layer 203, and a photoresist 205 are sequentially formed so as to cover the substrate 100 and the source electrode layer 217a and the drain electrode layer 217b formed in the aforementioned manner (FIG. 3A).

For the oxide semiconductor layer 201, the anti-light transmission layer 203, and the photoresist 205, materials such as those in Embodiment 1 can be used.

In this embodiment, the oxide semiconductor layer 201 is formed to a thickness of 100 nm by a sputtering method using an In—Ga—Zn—O-based oxide target. Further, the anti-light transmission layer 203 is formed to a thickness of 100 nm by a sputtering method using amorphous silicon.

Next, a method for selectively etching the oxide semiconductor layer 201 through a second photolithography process will be described.

First, exposure is performed using a photomask (not illustrated). As described in Embodiment 1, after passing through a resist mask, part of exposure light delivered to a portion not covered with the photomask reaches the anti-light transmission layer 203 but is mostly absorbed by the anti-light transmission layer 203. Thus, the exposure light hardly reaches the oxide semiconductor layer 201. Further, the amount of the exposure light which is transmitted through the substrate 100 and reaches a substrate stage (not illustrated) is reduced effectively.

Therefore, even when the substrate stage has an uneven shape due to a sucking hole or the like, the amount of the exposure light which reaches the substrate stage and the amount of light scattered by the uneven shape are reduced effectively. Consequently, the amount of light scattered by the substrate stage, which travels to enter the channel formation region of the oxide semiconductor layer 201, is reduced effectively.

As describe above, by providing the anti-light transmission layer 203 so that the substrate is closer to the anti-light transmission layer 203 than the photoresist 205, exposure light (not illustrated) is absorbed by the anti-light transmission layer 203 and does not reach the substrate stage (not illustrated). Thus, the channel formation region of the oxide semiconductor layer 201 can be prevented from being adversely affected by light regardless of the uneven shape of the substrate stage.

Note that light described above may be used as the exposure light. In this embodiment, an i line which is light having a spectrum of a high pressure mercury lamp is used as the exposure light.

After the exposure treatment, development treatment is performed, so that a resist mask 215 is formed (FIG. 3B).

Then, an unnecessary portion of the anti-light transmission layer 203 is etched using the resist mask 215. Etching may be performed by any method under the condition that the etching selectivity of the anti-light transmission layer 203 to the oxide semiconductor layer 201 is high. In this embodiment, the anti-light transmission layer 203 is etched using a tetramethylammonium hydroxide solution.

In that manner, the anti-light transmission layer 213 is obtained.

Then, the oxide semiconductor layer 201 is etched. In this embodiment, a method for forming the oxide semiconductor layer 211 with the use of the anti-light transmission layer 213 as a hard mask will be described.

First, the anti-light transmission layer 213 is formed and then the resist mask 215 is removed (FIG. 3C).

Next, an unnecessary portion of the oxide semiconductor layer 201 is etched using the anti-light transmission layer 213 as a hard mask. Etching may be performed by any method under the condition that the etching selectivity of the oxide semiconductor layer 201 to the anti-light transmission layer 213 is high. When dry etching is employed, the size of the pattern can be easily controlled and thus variation can be reduced.

Further, the anti-light transmission layer 213 also functions as a plasma protective layer in dry etching. Therefore, a portion of the oxide semiconductor layer 201, which is covered with the anti-light transmission layer 213, can be prevented from being damaged by plasma even when dry etching is employed.

In this embodiment, the unnecessary portion of the oxide semiconductor layer 201 is etched by dry etching, whereby the oxide semiconductor layer 211 is obtained.

Then, the anti-light transmission layer 213 over the oxide semiconductor layer 211 is removed by etching. Any etching method may be selected as long as the etching selectivity of the anti-light transmission layer 213 to the oxide semiconductor layer 211 is high; however, wet etching is preferably employed because the oxide semiconductor layer 211 can be prevented from being damaged by plasma.

In this embodiment, the anti-light transmission layer 213 is removed by wet etching with the use of a tetramethyl ammonium hydroxide solution.

Through the above process, the oxide semiconductor layer 211 is formed. Note that FIG. 3D is the schematic cross-sectional view at this stage.

Next, first heat treatment may be performed. Excessive water (including a hydroxyl group), hydrogen, or the like contained in the oxide semiconductor layer 211 can be removed by the first heat treatment. The temperature of the first heat treatment is higher than or equal to 350° C. and lower than the strain point of the substrate, preferably higher than or equal to 400° C. and lower than the strain point of the substrate.

The oxide semiconductor layer 211 can be dehydrated or dehydrogenated when the first heat treatment is performed at a temperature of 350° C. or higher, so that the concentration of hydrogen in the oxide semiconductor layer 211 can be lowered. When the first heat treatment is performed at a temperature of 450° C. or higher, the hydrogen concentration in the layer can be further reduced. When the first heat treatment is performed at a temperature of 550° C. or higher, the hydrogen concentration in the layer can be reduced still further.

As the atmosphere in which the first heat treatment is performed, it is preferable to use an inert gas that contains nitrogen or a rare gas (e.g., helium, neon, or argon) as its main component and does not contain water, hydrogen, or the like. For example, the purity of a gas introduced into a heat treatment apparatus can be 6N (99.9999%) or more, preferably 7N (99.99999%) or more. In this manner, the oxide semiconductor layer 211 is not exposed to the air during the first heat treatment so that entry of water or hydrogen can be prevented.

The heat treatment apparatus is not limited to an electric furnace and may be the one provided with a device for heating an object to be processed using heat conduction or heat radiation from a heating element such as a resistance heating element. An LRTA apparatus is an apparatus for heating an object to be processed by radiation of light (electromagnetic waves) emitted from a lamp such as a halogen lamp, a metal halide lamp, a xenon arc lamp, a carbon arc lamp, a high pressure sodium lamp, or a high pressure mercury lamp. A GRTA apparatus is an apparatus for heat treatment using a high temperature gas. As the high temperature gas, used is an inert gas which does not react with an object to be processed in heat treatment, such as nitrogen or a rare gas like argon.

In this embodiment, heat treatment is performed using a GRTA apparatus in a nitrogen atmosphere at 650° C. for 6 minutes as the first heat treatment.

Then, a silicon oxide film is formed to a thickness of 30 nm by a sputtering method as the gate insulating layer 207.

In this embodiment, the gate insulating layer 207 is formed with a single-layer structure of a silicon oxide film; however, the gate insulating layer is not limited thereto. The gate insulating layer can have a single-layer or layered structure including any of a silicon nitride film, a silicon oxynitride film, a silicon nitride oxide film, an aluminum oxide film, and the like. An oxide insulating layer is preferably used as a layer in contact with the oxide semiconductor layer. The gate insulating layer can be formed by a plasma CVD method, a sputtering method, or the like. In order to prevent the gate insulating layer from containing a large amount of hydrogen, the gate insulating layer is preferably formed by a sputtering method. There is no particular limitation on the thickness of the gate insulating layer; the thickness can be greater than or equal to 10 nm and less than or equal to 500 nm, for example.

Next, the gate electrode layer 219 is formed. The gate electrode layer 219 can be formed in such a manner that a conductive layer is formed over the gate insulating layer 207 and is selectively etched through a third photolithography process.

The conductive layer to be the gate electrode layer 219 can be formed as a single layer or a stack using a metal material such as molybdenum, titanium, chromium, tantalum, tungsten, aluminum, copper, neodymium, or scandium or an alloy material which contains any of these materials as its main component. When such a material is used, exposure light used in patterning the gate electrode layer 219 is reflected by the conductive layer and thus is not transmitted through the conductive layer so as not to travel to the substrate side. Accordingly, there is no possibility that light scattered by the substrate stage travels to enter the channel formation region of the oxide semiconductor layer 211.

In this embodiment, a tungsten film with a thickness of 200 nm is used as the gate electrode layer 219.

Then, the protective insulating layer 209 is formed. The protective insulating layer 209 can be formed to a thickness of 1 nm or more by a method by which impurities such as water and hydrogen do not enter the protective insulating layer 209, such as a sputtering method, as appropriate. When hydrogen is contained in the protective insulating layer 209, entry of the hydrogen into the oxide semiconductor layer 211, or extraction of oxygen in the oxide semiconductor layer 211 by hydrogen may occur, thereby causing part of the oxide semiconductor layer 211 to have lower resistance, so that a parasitic channel might be formed. Therefore, it is important that a deposition method in which hydrogen is not used be employed in order to form the protective insulating layer 209 containing as little hydrogen as possible.

In this embodiment, as the protective insulating layer 209, a silicon oxide film is formed to a thickness of 30 nm by a sputtering method.

Second heat treatment may be performed after formation of the protective insulating layer 209. The second heat treatment can be performed in the air, an inert gas atmosphere, or an oxygen gas atmosphere at a temperature higher than or equal to 100° C. and lower than or equal to 200° C. Alternatively, the following change in the heating temperature may be conducted repeatedly: the heating temperature is increased from a room temperature to a temperature higher than or equal to 100° C. and lower than or equal to 200° C. and then decreased to a room temperature. For example, the second heat treatment is performed at 150° C. for an hour in a nitrogen atmosphere.

Through the above process, the thin film transistor 200 is formed. FIG. 3E is a schematic cross-sectional view at this stage.

In forming the oxide semiconductor layer 211, the anti-light transmission layer 213 is used as a hard mask; however, the resist mask 215 may be used. When the resist mask 215 is used, the oxide semiconductor layer 201 and the anti-light transmission layer 203 can be etched either separately or simultaneously. Dry etching is preferable as an etching method because the size of the pattern can be easily controlled and thus variation thereof can be reduced.

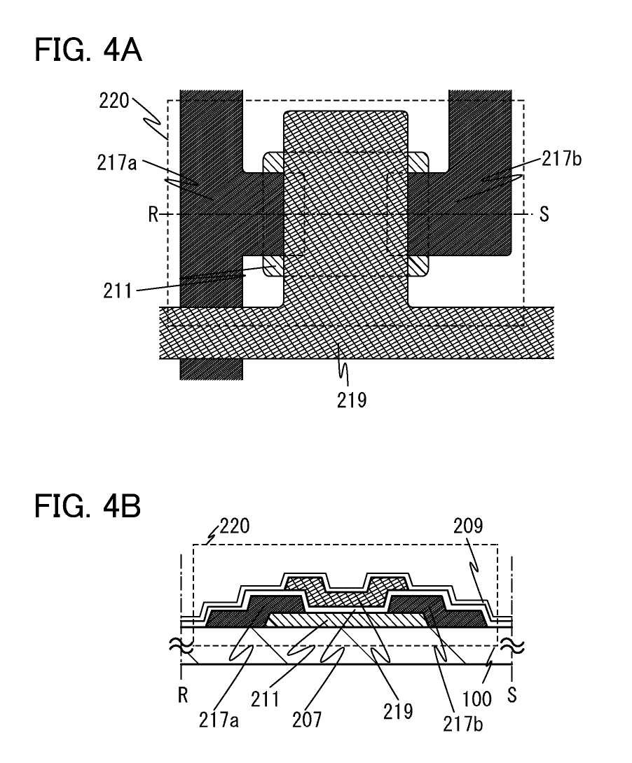

Although the staggered thin film transistor is formed in this embodiment, the oxide semiconductor layer 211 may be formed before formation of the source electrode layer 217a and the drain electrode layer 217b. Through such a process, a so-called top-contact thin film transistor in which the source electrode layer 217a and the drain electrode layer 217b are in contact with a top surface of the oxide semiconductor layer 211 which is even can be formed as illustrated in FIGS. 4A and 4B. Here, FIGS. 4A and 4B are a schematic top view of a thin film transistor 220 and a schematic cross-sectional view along R-S in FIG. 4A, respectively.

As described above, a thin film transistor is formed by a method which enables reduction in the amount of light scattered by a substrate stage, which travels to enter the oxide semiconductor layer, in patterning the oxide semiconductor layer. Thus, damage to the oxide semiconductor layer due to light depending on a pattern of the substrate stage can be suppressed. Accordingly, variation in electrical characteristics in a substrate surface can be reduced. By applying such a thin film transistor to a semiconductor device such as an image display device or an image sensor, the semiconductor device can have little variation in emission luminance or the like.

This embodiment can be combined as appropriate with any of the other embodiments in this specification.

### Embodiment 3

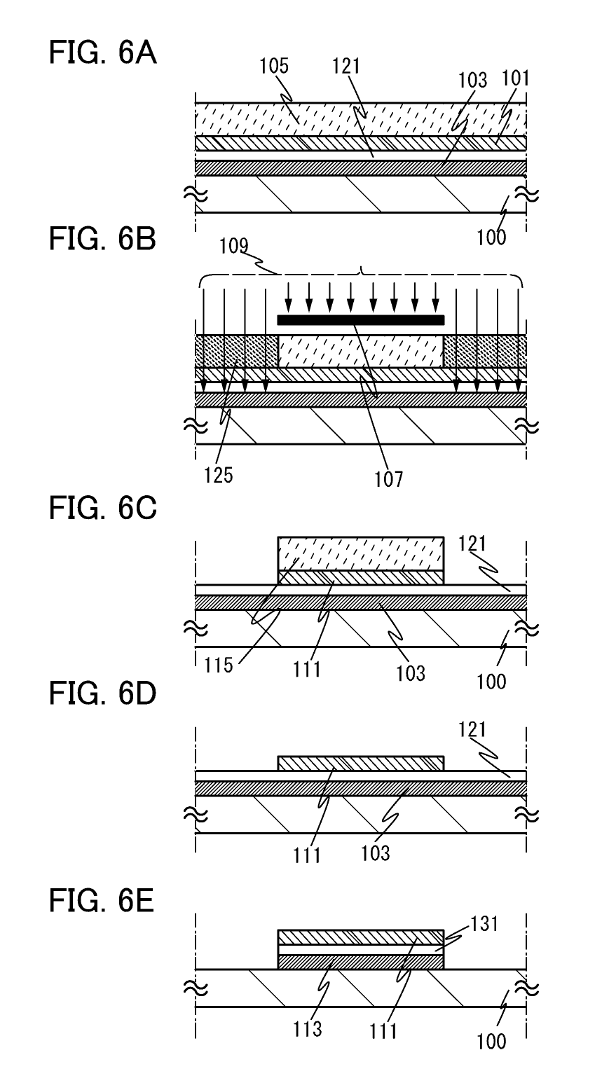

In this embodiment, a method for forming an oxide semiconductor layer, in which an influence of light in patterning is suppressed, which is different from the method described in Embodiment 1, will be described with reference to FIGS. 6A to 6E.

Description will be made on a method for forming the island-shaped oxide semiconductor layer 111 over a layered film including the anti-light transmission layer 103 (or 113) and a base layer 121 (or 131), which is formed over the light-transmitting substrate 100, as exemplified in FIGS. 6D and 6E.

First, as illustrated in FIG. 6A, the anti-light transmission layer 103, the base layer 121, the oxide semiconductor layer 101, and the photoresist 105 are sequentially formed over the light-transmitting substrate 100.

For the light-transmitting substrate 100, a material such as that described in Embodiment 1 can be used.

In this embodiment, a glass substrate is used as the light-transmitting substrate 100.

Similarly, the anti-light transmission layer 103 and the oxide semiconductor layer 101 can be formed using a material such as that described in Embodiment 1.

In this embodiment, an amorphous silicon film with a thickness of 100 nm is used as the anti-light transmission layer 103. The amorphous silicon film is formed by a sputtering method in a high-purity gas atmosphere in which impurities such as water, hydrogen, a hydroxyl group, and hydride are removed.

As the oxide semiconductor layer 101, an In—Ga—Zn—O-based oxide semiconductor film with a thickness of 100 nm is used. The oxide semiconductor layer 101 is formed by a sputtering method as in Embodiment 1.

The base layer 121 is sandwiched between the anti-light transmission layer 103 and the oxide semiconductor layer 101 and has a function of preventing diffusion of impurity elements from the substrate 100. Thus, it is not necessary to provide the base layer 121 if it is not required. The base layer 121 is preferably formed so as to contain impurities such as hydrogen and water as little as possible because it is in contact with the oxide semiconductor layer 101.

The base layer 121 can be formed to have a single-layer structure or a layered structure including one or more selected from a silicon nitride film, a silicon oxide film, a silicon nitride oxide film, and a silicon oxynitride film.

In this embodiment, as the base layer 121, a silicon oxide film is formed to have a thickness of 50 nm by a sputtering method in a high-purity inert gas in which impurities such as water, hydrogen, a hydroxyl group, and hydride are removed.

As the photoresist 105, a positive photoresist is used as in Embodiment 1. Therefore, a portion of the photoresist 105, which is irradiated with light, is removed by development treatment to be performed later.

Next, exposure treatment is performed using the photomask 107 (see FIG. 6B). A portion of the photoresist 105, which is covered with the photomask 107, is shielded from the exposure light 109 by the photomask 107 and thus is not exposed to light. On the other hand, a portion of the photoresist 105, which is not covered with the photomask 107, is irradiated with the exposure light 109. The photoresist 105 is exposed to the exposure light 109 to form the modified photoresist 125.

Note that light described in Embodiment 1 may be used as the exposure light 109. In this embodiment, an i line which is light having a spectrum of a high pressure mercury lamp is used as the exposure light 109.

Here, the portion of the photoresist 105, which is covered with the photomask 107, is shielded from the exposure light 109 by the photomask 107 and thus is not irradiated with the exposure light 109. Therefore, a portion of the oxide semiconductor layer 101, which is covered with the photomask 107, is not adversely affected by light.

Part of the exposure light 109 passes through the photoresist 125 and then reaches the portion of the oxide semiconductor layer 101, which is not covered with the photomask 107. However, the portion of the oxide semiconductor layer 101 is removed by etching treatment to be performed later; thus, the influence of light does not matter.

Part of the exposure light 109 which passes through the oxide semiconductor layer 101 is transmitted through the base layer 121 and reaches the anti-light transmission layer 103 but is mostly absorbed by the anti-light transmission layer 103. Thus, the amount of the exposure light 109 which is transmitted through the substrate 100 and reaches a substrate stage (not illustrated) is reduced effectively.

Therefore, even when the substrate stage has an uneven shape due to a sucking hole or the like, the amount of the exposure light 109 which reaches the substrate stage and is scattered by the uneven shape is reduced effectively. Consequently, it is possible to effectively reduce the amount of light scattered by the substrate stage, which travels to enter a portion of the oxide semiconductor layer 101, which is not removed by etching of the oxide semiconductor layer 101. Thus, the oxide semiconductor layer 101 can be prevented from being adversely affected by light.

Further, in this embodiment, the anti-light transmission layer 103 is provided so that the substrate is closer to the anti-light transmission layer 103 than the oxide semiconductor layer 101. Thus, even when the exposure light 109 is not absorbed completely by the anti-light transmission layer 103 and partly reaches the substrate stage, light scattered by the substrate stage is absorbed by the anti-light transmission layer 103 before reaching the oxide semiconductor layer 101. Therefore, with such a structure, light scattered by the substrate stage can be more effectively prevented from adversely affecting the oxide semiconductor layer 101.

When a material which reflects the exposure light 109 is used for the anti-light transmission layer, part of the exposure light 109 reflected by the anti-light transmission layer travels to enter a portion of the oxide semiconductor layer 101, which is not removed by etching of the oxide semiconductor layer 101, in some cases. However, the oxide semiconductor layer 101 and the base layer 121 are sufficiently thin; thus, a portion of the oxide semiconductor layer 101, where part of the exposure light 109 reflected by the anti-light transmission layer enters, is small, which does not lead to variation in electrical characteristics substantially.

After the exposure treatment, development treatment is performed. Through the develop treatment, a portion of the photoresist 125 which is not covered by the photomask 107 is removed. In that manner, the resist mask 115 is formed.

Next, an unnecessary portion of the oxide semiconductor layer 101 is etched using the resist mask 115, so that the island-shaped oxide semiconductor layer 111 is formed (FIG. 6C). After that, the resist mask 115 is removed.

In such a manner, the island-shaped oxide semiconductor layer 111 formed over the anti-light transmission layer 103 and the base layer 121 is obtained (FIG. 6D).

Note that the anti-light transmission layer 103 and the base layer 121 may be patterned into island shapes similar to that of the oxide semiconductor layer 111. In that case, an unnecessary portion of the oxide semiconductor layer 111 is etched and then unnecessary portions of the anti-light transmission layer 103 and the base layer 121 are etched using the resist mask 115, so that the anti-light transmission layer 113 and the base layer 131 having island shapes are formed. After that, the resist mask 115 is removed. Consequently, formed is an island-shaped pattern in which the anti-light transmission layer 113, the base layer 131, and the oxide semiconductor layer 111 are sequentially stacked, which is illustrated in FIG. 6E.

By forming the oxide semiconductor layer 111 as described above, the oxide semiconductor layer 111 can be formed without being adversely affected by light from the exposure apparatus in the patterning. Therefore, when an oxide semiconductor layer formed through such a forming process is applied to a semiconductor device such as a thin film transistor, the semiconductor device can have little variation in electrical characteristics.

### Embodiment 4

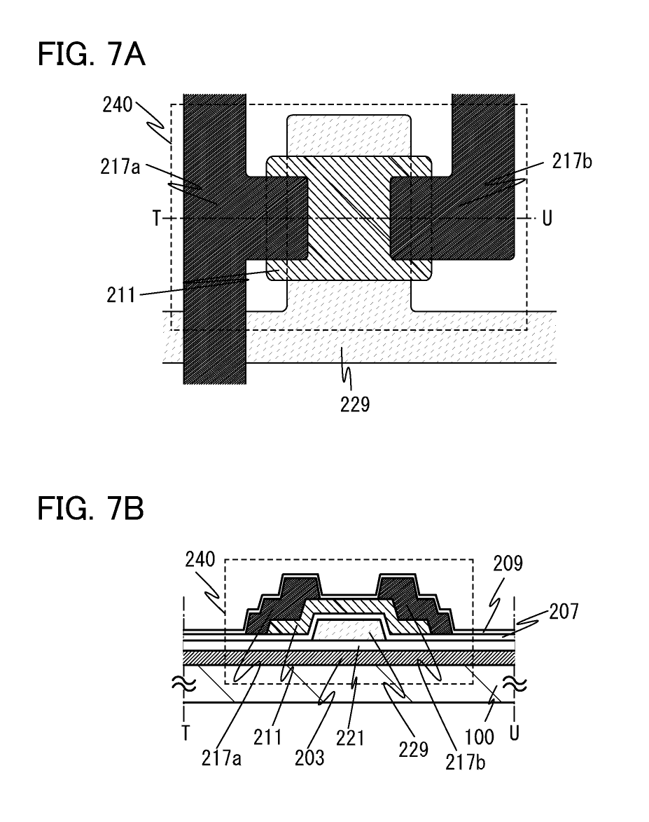

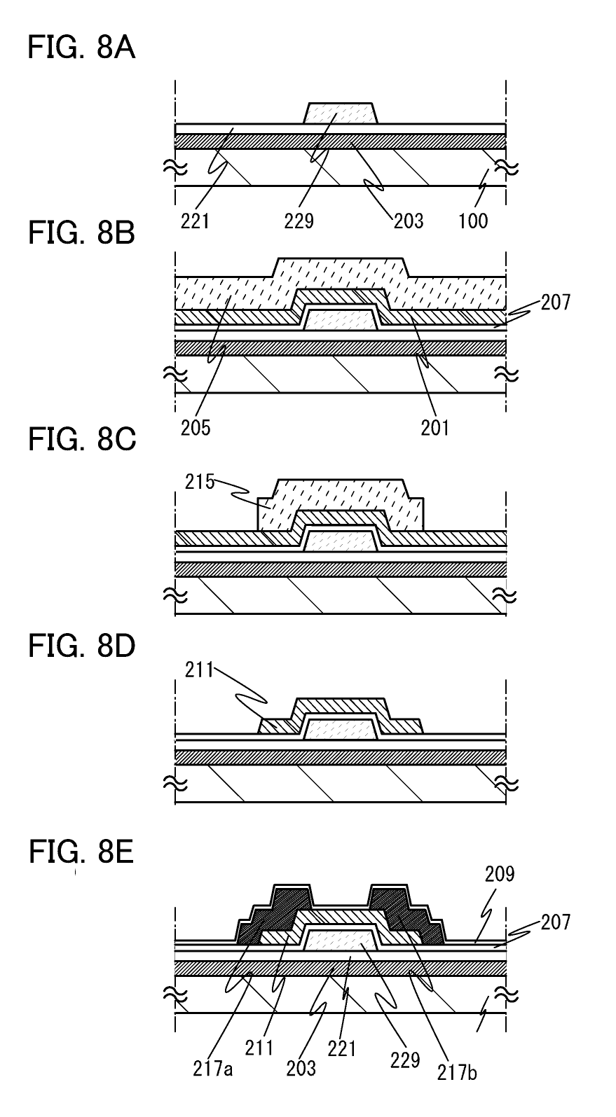

In this embodiment, an example of a method for manufacturing a thin film transistor having a structure different from that in Embodiment 2 and including the oxide semiconductor layer formed by the forming method in Embodiment 3 will be described with reference to FIGS. 7A and 7B, and FIGS. 8A to 8E.

FIGS. 7A and 7B illustrate a structure of a bottom-gate thin film transistor 240 (hereinafter referred to as the thin film transistor 240) exemplified in this embodiment. FIGS. 7A and 7B are a schematic top view of the thin film transistor 240 and a schematic cross-sectional view along T-U in FIG. 7A, respectively.

The thin film transistor 240 includes the anti-light transmission layer 203, a base layer 221, a light-transmitting gate electrode layer 229, the gate insulating layer 207, the oxide semiconductor layer 211, the source electrode layer 217a, the drain electrode layer 217b, and the protective insulating layer 209. The anti-light transmission layer 203 and a base layer 221 are sequentially stacked over the light-transmitting substrate 100. The light-transmitting gate electrode layer 229 is in contact with the base layer 221. The gate insulating layer 207 covers an exposed portion of the base layer 221 and the gate electrode layer 229. The oxide semiconductor layer 211 is in contact with the gate insulating layer 207 and overlaps with the gate electrode layer 229. The source electrode layer 217a and the drain electrode layer 217b are in contact with the oxide semiconductor layer 211 and overlap with end portions of the gate electrode layer 229. The protective insulating layer 209 covers exposed portions of the gate insulating layer 207 and the oxide semiconductor layer 211 and the source electrode layer 217a and the drain electrode layer 217b.

Next, a manufacturing method of the thin film transistor 240 will be described with reference to FIGS. 8A to 8E.

First, the anti-light transmission layer 203 and the base layer 221 are formed over the substrate 100.

As the substrate 100, a light-transmitting substrate is used as in Embodiment 1.

For the anti-light transmission layer 203, a material such as that in Embodiment 1 can be used. In this embodiment, the anti-light transmission layer 203 is formed to a thickness of 100 nm by a sputtering method using amorphous silicon.

For the base layer 221, a material similar to that in Embodiment 3 can be used. In this embodiment, as the base layer 221, a silicon oxide film is formed to a thickness of 50 nm by a sputtering method in a high-purity inert gas.

Formation of the base layer 221 between the oxide semiconductor layer 201, which is to be formed through a process below, and the substrate 100 enables effective suppression of diffusion of impurity elements from the substrate 100 to the oxide semiconductor layer 201. In addition, amorphous silicon which is a semiconductor is used for the anti-light transmission layer in this embodiment; thus, contact between the anti-light transmission layer 203 and the oxide semiconductor layer 201 might adversely affect electrical characteristics. The base layer 221 also has a function of preventing the contact therebetween.

Next, the light-transmitting gate electrode layer 229 is formed over the base layer 221.

A light-transmitting material is used for the gate electrode layer 229. Since the bottom-gate thin film transistor described in this embodiment has the anti-light transmission layer 203, the amount of the exposure light 109 which is transmitted through the substrate 100 and reaches a substrate stage in patterning the oxide semiconductor layer is reduced effectively. Further, even when the exposure light 109 is not absorbed completely by the anti-light transmission layer 103 and partly reaches the substrate stage, light scattered by the substrate stage is absorbed by the anti-light transmission layer 103 before reaching the oxide semiconductor layer 101. Therefore, the light scattered by the substrate stage is not transmitted through the gate electrode layer 229, thereby a channel formation region of the oxide semiconductor layer 211 is not likely to be adversely affected by the light.

As a material used for the light-transmitting gate electrode layer 229, for example, a conductive metal oxide can be used. As the conductive metal oxide, an indium oxide (In₂O₃), a tin oxide (SnO₂), a zinc oxide (ZnO), an indium oxide-tin oxide alloy (In₂O₃—SnO₂, abbreviated to ITO), an indium oxide-zinc oxide alloy (In₂O₃—ZnO), or any of these metal oxide materials containing a silicon oxide can be used.

Although a light-transmitting material is used for the gate electrode layer 229 in this embodiment, a material not transmitting light, such as that in Embodiment 2, may be used. In the case where such a material is used, even when the light scattered by the substrate stage is not absorbed completely by the anti-light transmission layer 103, the light is reflected by the gate electrode layer, so that the channel formation region of the oxide semiconductor layer 211 is not likely to be adversely affected by the light.

The gate electrode layer 229 can be formed in such a manner that a conductive layer is formed over the base layer 221 and is selectively etched through a first photolithography process. In this embodiment, as a conductive layer to be the gate electrode layer 229, an ITO film is formed to a thickness of 150 nm by a sputtering method. FIG. 8A is a schematic cross-sectional view at that time.

The gate insulating layer 207, the oxide semiconductor layer 201, and the photoresist 205 are sequentially formed so as to cover the gate electrode layer 229 formed in such a manner and an exposed portion of the base layer 221 (FIG. 8B).

For the gate insulating layer 207, a material such as that described in Embodiment 2 can be used. In this embodiment, a silicon oxide film is formed to a thickness of 30 nm by a sputtering method as the gate insulating layer 207.

For the oxide semiconductor layer 201, a material such as that described in Embodiment 1 can be used. In this embodiment, the oxide semiconductor layer 201 is formed to a thickness of 100 nm by a sputtering method using an In—Ga—Zn—O-based oxide target.

For the photoresist 205, a positive photosensitive material is used as in Embodiment 1.

Next, a method for selectively etching the oxide semiconductor layer 201 through a second photolithography process will be described.

First, exposure is performed using a photomask (not illustrated). As described above, a portion covered with the photomask is shielded from exposure light by the photomask and thus a portion of the oxide semiconductor layer 201, which is covered with the photomask, is not irradiated with the exposure light. Therefore, the portion of the oxide semiconductor layer 201 is not adversely affected by light. Further, part of the exposure light (not illustrated) delivered to a portion not covered with the photomask passes through the photoresist 205 and then is delivered to the oxide semiconductor layer 201. However, a portion of the oxide semiconductor layer 201, which is not covered with the photomask, is removed by etching treatment to be performed later; thus, the influence of light does not matter.

Part of the exposure light which passes through the oxide semiconductor layer 201 is transmitted through the gate insulating layer 207 and the base layer 221 and reaches the anti-light transmission layer 203 but is mostly absorbed by the anti-light transmission layer 203. Thus, the amount of the exposure light which is transmitted through the substrate 100 and reaches a substrate stage (not illustrated) is reduced effectively.

Therefore, even when the substrate stage has an uneven shape due to a sucking hole or the like, the amount of the exposure light which reaches the substrate stage and is scattered by the uneven shape is reduced effectively. Consequently, it is possible to effectively reduce the amount of light scattered by the substrate stage, which travels to enter a portion of the oxide semiconductor layer 201, which is not removed by etching of the oxide semiconductor layer 201. Thus, the oxide semiconductor layer 201 can be prevented from being adversely affected by light.

Further, in this embodiment, the anti-light transmission layer 203 is provided so that the substrate is closer to the anti-light transmission layer 203 than the oxide semiconductor layer 201. Thus, even when the exposure light is not absorbed completely by the anti-light transmission layer 203 and partly reaches the substrate stage, light scattered by the substrate stage is absorbed by the anti-light transmission layer 203 before reaching the oxide semiconductor layer 201. Therefore, with such a structure, light scattered by the substrate stage can be prevented from adversely affecting the oxide semiconductor layer 201 more effectively.

When a material which reflects the exposure light is used for the anti-light transmission layer, part of the exposure light reflected by the anti-light transmission layer travels to enter a portion of the oxide semiconductor layer 201, which is not removed by etching of the oxide semiconductor layer 201, in some cases. However, the oxide semiconductor layer 201, the gate insulating layer 207 and the base layer 221 are sufficiently thin; thus, a portion where part of the exposure light reflected by the anti-light transmission layer enters is small, which does not lead to variation in electrical characteristics substantially.

As describe above, by providing the anti-light transmission layer 203 so that the substrate is closer to the anti-light transmission layer 203 than the oxide semiconductor layer 201, the exposure light and the light scattered by the substrate stage are absorbed by the anti-light transmission layer 203. Thus, the channel formation region of the oxide semiconductor layer 201 can be prevented from being adversely affected by light regardless of the uneven shape of the substrate stage.

Note that light described in Embodiment 1 can be used as exposure light. In this embodiment, an i line which is light having a spectrum of a high pressure mercury lamp is used as the exposure light.

After the exposure treatment, development treatment is performed, so that the resist mask 215 is formed (FIG. 8C).

Then, an unnecessary portion of the oxide semiconductor layer 201 is etched using the resist mask 215. Here, wet etching is preferably employed as an etching method because the oxide semiconductor layer 201 is not damaged by plasma. In this embodiment, the oxide semiconductor layer 201 is etched using a mixed acid containing an acetic acid, a nitric acid, and a phosphoric acid, so that the island-shaped oxide semiconductor layer 211 is formed.

After the oxide semiconductor layer 211 is formed, the resist mask 215 is removed; thus, a shape illustrated in FIG. 8D is obtained.

After formation of the oxide semiconductor layer 211 and removal of the resist mask 215, first heat treatment may be performed. Conditions of the first heat treatment, such as the temperature and time, may be set optimally in consideration of heat resistance of a material used for the gate electrode layer 229.

The first heat treatment may be performed on the oxide semiconductor layer 201 which has not yet been processed into the island-shaped oxide semiconductor layer 211. In that case, the second photolithography process is performed after the first heat treatment.

Next, the source electrode layer 217a and the drain electrode layer 217b are formed. The source electrode layer 217a and the drain electrode layer 217b can be formed in such a manner that a conductive layer is formed over an exposed portion of the gate insulating layer 207 and the oxide semiconductor layer 211 and is selectively etched through a third photolithography process.

As a material of the conductive layer to be the source electrode layer 217a and the drain electrode layer 217b, a material such as that described in Embodiment 1 can be used.

In this embodiment, a Ti film with a thickness of 200 nm is used as a conductive layer to be the source electrode layer 217a and the drain electrode layer 217b.

Note that it is preferable that etching conditions be optimized so that the oxide semiconductor layer 211 is not etched and divided when the conductive layer is etched. However, it is difficult to obtain etching conditions in which only the conductive layer is etched and the oxide semiconductor layer 211 is not etched at all. In some cases, only part of the oxide semiconductor layer 211 is etched, so that the oxide semiconductor layer 211 having a groove portion (recessed portion) is formed when the conductive layer is etched.

Then, the protective insulating layer 209 is formed. The protective insulating layer 209 can be formed using a material and a method, such as those described in Embodiment 2. Note that it is important that a deposition method in which hydrogen is not used be employed in order to form the protective insulating layer 209 containing as little hydrogen as possible. When hydrogen is contained in the protective insulating layer 209, entry of the hydrogen into the oxide semiconductor layer 211, or extraction of oxygen in the oxide semiconductor layer 211 by hydrogen may occur, thereby causing a back channel of the oxide semiconductor layer 211 to have lower resistance, so that a parasitic channel might be formed.

In this embodiment, as the protective insulating layer 209, a silicon oxide film is formed to a thickness of 30 nm by a sputtering method.

Second heat treatment may be performed after formation of the protective insulating layer 209. Conditions of the second heat treatment, such as the temperature and time, may be set optimally in consideration of heat resistance of a material used for the gate electrode layer 229.

Through the above process, the thin film transistor 240 is formed. FIG. 8E is a schematic cross-sectional view at that time.

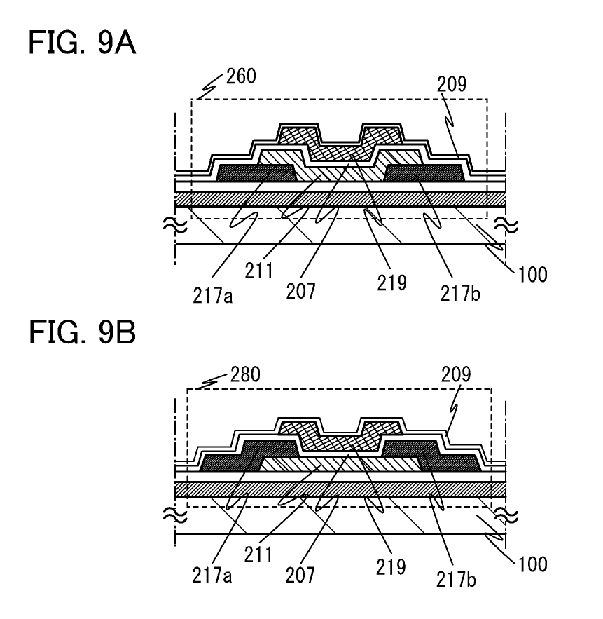

In this embodiment, the manufacturing method of the bottom-gate thin film transistor 240 is described. Note that an embodiment of the present invention can also be applied to a manufacturing process of a top-gate thin film transistor such as that in FIGS. 9A and 9B. FIG. 9A illustrates a structure of a so-called bottom-contact thin film transistor 260 where the source electrode layer 217a and the drain electrode layer 217b are in contact with a bottom surface of the oxide semiconductor layer 211. FIG. 9B illustrates a so-called top-contact thin film transistor 280 where the source electrode layer 217a and the drain electrode layer 217b are in contact with a top surface of the oxide semiconductor layer 211. In such thin film transistors, it is also possible to effectively suppress an adverse effect of light scattered by the substrate stage, when the anti-light transmission layer is provided so that the substrate is closer to the anti-light transmission layer than the oxide semiconductor layer.

As described above, a thin film transistor is formed by a method which enables reduction in the amount of light scattered by a substrate stage, which travels to enter the oxide semiconductor layer, in patterning the oxide semiconductor layer. Thus, damage to the oxide semiconductor layer due to light depending on a pattern of the substrate stage can be suppressed. Accordingly, variation in electrical characteristics in a substrate surface of the thin film transistor can be reduced. By applying such a thin film transistor to a semiconductor device such as an image display device or an image sensor, the semiconductor device can have little variation in emission luminance or the like.

This embodiment can be combined as appropriate with any of the other embodiments in this specification.

This application is based on Japanese Patent Application serial no. 2010-116128 filed with the Japan Patent Office on May 20, 2010, the entire contents of which are hereby incorporated by reference.

What is claimed is:

1. A method for manufacturing a semiconductor device, comprising:
forming a layer comprising an oxide semiconductor over a light-transmitting substrate;
forming an anti-light transmission layer which absorbs or reflects light within a wavelength band absorbed by the oxide semiconductor, over the layer comprising the oxide semiconductor;
forming a photoresist layer over the anti-light transmission layer;
irradiating the photoresist layer with the light to form a resist mask over the anti-light transmission layer;
patterning the anti-light transmission layer by using the resist mask; and
removing the layer comprising the oxide semiconductor except for a portion which overlaps with the patterned anti-light transmission layer.

2. The method according to claim 1, wherein the anti-light transmission layer comprises silicon or aluminum.

3. The method according to claim 1, wherein a wavelength of the light is 365 nm or lower.

4. The method according to claim 1, wherein the light has a spectrum of a high pressure mercury lamp.

5. The method according to claim 1 further comprising:
removing the anti-light transmission layer.

6. A method for manufacturing a semiconductor device, comprising:
forming an anti-light transmission layer which absorbs or reflects light within a wavelength band absorbed by an oxide semiconductor, over a light-transmitting substrate,
forming a layer comprising the oxide semiconductor over the anti-light transmission layer;
forming a photoresist layer over the layer comprising the oxide semiconductor;
irradiating the photoresist layer with the light to form a resist mask over the layer comprising the oxide semiconductor; and
removing the layer comprising the oxide semiconductor except for a portion overlapping with the resist mask.

7. The method according to claim 6, wherein the anti-light transmission layer comprises silicon or aluminum.

8. The method according to claim 6, wherein a wavelength of the light is 365 nm or lower.

9. The method according to claim 6, wherein the light has a spectrum of a high pressure mercury lamp.

10. The method according to claim 6 further comprising:
forming an insulating film between the anti-light transmission layer and the layer comprising the oxide semiconductor.

11. A method for manufacturing a semiconductor device, comprising:
forming a source electrode layer and a drain electrode layer which are apart form each other over a light-transmitting substrate;
forming a layer comprising an oxide semiconductor which covers end portions of the source electrode layer and the drain electrode layer and a space between the source electrode layer and the drain electrode layer;
forming an anti-light transmission layer which absorbs or reflects light within a wavelength band absorbed by the oxide semiconductor, over the layer comprising the oxide semiconductor;
forming a photoresist layer over the anti-light transmission layer;
irradiating the photoresist layer with the light to form a resist mask which overlaps with the end portions of the source electrode layer and the drain electrode layer and the space over the anti-light transmission layer;
patterning the anti-light transmission layer by using the resist mask;
removing the layer comprising the oxide semiconductor except for a portion which overlaps with the patterned anti-light transmission layer;
forming a gate insulating layer in contact with the layer comprising the oxide semiconductor; and
forming a gate electrode layer so that it is in contact with the gate insulating layer and overlaps with the space.

12. The method according to claim 11, wherein the anti-light transmission layer comprises silicon or aluminum.

13. The method according to claim 11, wherein a wavelength of the light is 365 nm or lower.

14. The method according to claim 11, wherein the light has a spectrum of a high pressure mercury lamp.

15. The method according to claim 11 further comprising:
removing the anti-light transmission layer.

16. A method for manufacturing a semiconductor device, comprising:
forming an anti-light transmission layer which absorbs or reflects light within a wavelength band absorbed by an oxide semiconductor, over a light-transmitting substrate;
forming a layer comprising the oxide semiconductor over the anti-light transmission layer;
forming a photoresist layer over the layer comprising the oxide semiconductor;
irradiating the photoresist layer with the light to form a resist mask over the layer comprising the oxide semiconductor;
removing the layer comprising the oxide semiconductor except for a portion overlapping with the resist mask;
forming a source electrode layer and a drain electrode layer which are apart from each other and in contact with the layer comprising the oxide semiconductor;
forming a gate insulating layer in contact with the layer comprising the oxide semiconductor and end portions of the source electrode layer and the drain electrode layer;
forming a gate electrode layer which is in contact with the gate insulating layer and overlaps with the layer comprising the oxide semiconductor and a space between the source electrode layer and the drain electrode layer.

17. The method according to claim 16, wherein the anti-light transmission layer comprises silicon or aluminum.

18. The method according to claim 16, wherein a wavelength of the light is 365 nm or lower.

19. The method according to claim 16, wherein the light has a spectrum of a high pressure mercury lamp.

20. The method according to claim 16 further comprising:
forming an insulating film between the anti-light transmission layer and the layer comprising the oxide semiconductor.
